(19) United States
(12) Patent Application Publication
(10) Pub. No.: US 2009/0025773 A1
(43) Pub. Date: Jan. 29, 2009

(54) Thermoelectric generator with micro-electrostatic energy converter

(76) Inventor: Ingo Stark, Riverside, CA (US)

Correspondence Address: NovaTech IP Law, 1001 Avenue Pico, Suite C500, San Clemente, CA, 92673, US

(21) Appl. No.: 11/518,441

(22) Filed: Sep. 8, 2006

Related U.S. Application Data
(60) Provisional application No. 60/809,479, filed on May 31, 2006.

(51) Int. Cl. H01L 35/30; H01L 35/04

(52) U.S. Cl. 136/212; 136/205

(57) ABSTRACT

A power supply comprises a thermoelectric generator, an initial energy management assembly, an electrostatic converter and a final energy management assembly. The thermoelectric generator is adapted to generate an electrical activation energy with sufficiently high voltage in response to a temperature gradient acting across the thermoelectric generator. The initial energy management assembly is connected to the thermoelectric generator and is adapted to receive and condition the electrical activation energy produced by the thermoelectric generator. The electrostatic converter is connected to the initial energy management assembly and is activatable by the electrical activation energy received therefrom and is configured to generate electrical energy in response to vibrational energy acting thereupon. The final energy management assembly is connected to the electrostatic converter and is adapted to condition the electrical energy produced thereby.

### CROSS-REFERENCE TO RELATED APPLICATIONS

The present application claims priority to co-pending U.S. Provisional Application No. 60/809,479 entitled THERMOELECTRIC GENERATOR WITH MICOELECTROSTATIC ENERGY CONVERTER filed on May 31, 2006, the entire contents of which is expressly incorporated by reference herein. The present application is also related to U.S. patent application Ser. No. 11/352,113 filed on Feb. 10, 2006 and entitled Improved Low Power Thermoelectric Generator, which is a continuation-in-part application of U.S. application Ser. No. 11/185,312, filed on Nov. 17, 2005 and entitled Low Power Thermoelectric Generator, which is a continuation application of U.S. application Ser. No. 10/440,992 filed on May 19, 2003 and entitled Low Power Thermoelectric Generator, now U.S. Pat. No. 6,958,443, the entire contents of each being expressly incorporated by reference herein.

### STATEMENT RE: FEDERALLY SPONSORED RESEARCH/DEVELOPMENT

(Not Applicable)

### BACKGROUND

The present invention pertains generally to power generation and, more particularly, to a self-sufficient power supply comprising a combination of thermoelectric energy conversion and electrostatic or mechanical energy conversion and which is specifically adapted to produce electrical power such as may be used by microelectronic devices and systems.

The increasing trend toward miniaturization of microelectronic devices necessitates the development of miniaturized power supplies. Batteries and solar cells are traditional power sources for such microelectronic devices. However, power that is supplied by batteries dissipates over time requiring that the batteries be periodically replaced. Solar cells, although having an effectively unlimited useful life, may only provide a transient source of power as the sun or other light sources may not always be available. Furthermore, solar cells require periodic cleaning of their surfaces in order to maintain efficiency of energy conversion.

Thermoelectric generators are self-sufficient energy sources that convert thermal energy into electrical energy according to the Seebeck effect—a phenomenon whereby heat differences may be converted into electricity due in large part to charge carrier diffusion in a conductor. Electrical power may be generated under the Seebeck effect by utilizing thermocouples which are each comprised of a pair of dissimilar metals (n-type and p-type) joined at one end. N-type and p-type, respectively, refers to the negative and positive types of charge carriers within the material.

The temperature gradient that exists between the ends of the thermocouple may be artificially applied or it may be naturally-occurring as waste heat or as dissipated heat that is constantly rejected by the human body. In a wristwatch, one side is exposed to air at ambient temperature while the opposite side is exposed to the higher temperature of the wearer's skin. Thus, a small temperature gradient is typically present across the thickness of the wristwatch. A thermoelectric generator may be incorporated into the wristwatch to take advantage of the dissipated or waste heat and generate a supply of power sufficient to operate the wristwatch as a self-contained unit. Advantageously, many microelectronic devices that are similar in size to a typical wristwatch require only a small amount of power and therefore may also be compatible for powering by a thermoelectric generator.

Another self-sufficient energy source capable of generating power from environmental or ambient energy are vibration-based devices. Recent research into methods for exploiting vibration-based energy sources resulted in significant developments in variable capacitors for use in electro-static micropower generators. Due to the ubiquitousness of vibration sources readily available in many locations such as automobile engines, microwave ovens and office windows that are located adjacent heavily-traveled roadways, many opportunities exist for converting mechanical energy into electrical energy for powering microelectronic devices and systems.

In contrast to solar energy which is generally available on a transient basis, vibrational sources and thermal gradients are generally available on a more consistent basis. Vibrational energy may be converted into electrical energy under several principles. For example, electromagnetic converters generate an electric current in response to relative motion between a magnetic field and a coil. Piezoelectric converters generate electrical energy in response to applied mechanical stress as a result of slight deformation of a piezoelectric element. More specifically, a piezoelectric converter typically includes a dielectric material which, in response to mechanical strain acting thereupon, generates a charge separation across a dielectric material which generates a voltage.

Electrostatic converters may be constructed as a variable capacitor and are configured to convert mechanical energy into electrical energy as a result of mechanical movement against an electric field formed between a pair of plates that comprise the variable capacitor. More specifically, in electrostatic converters, the plates (i.e., conductors) are separated by a dielectric and are operative to move relative to one another in response to vibration acting against one of the plates. The movement as a result of vibration acting against the electric field between the two plates results in a change of energy stored within the capacitor. In this manner, electrostatic converters can be used to convert vibrational energy into electrical energy.

In comparing the three types of mechanical-energy/electrical-energy conversion devices (i.e., electromagnetic, piezoelectric, and electrostatic), electrostatic converters offer several advantages. For example, the increasing miniaturization of many microelectronic devices is due in part to advances in micro-electro-mechanical systems (MEMS). The ability to manufacture electrostatic converters utilizing MEMS technology facilitates the integration of electrostatic converters into many electronics Microsystems and also allows for an overall reduction in the size of the electronic device that is to be powered by the electrostatic converter.

In addition, unlike piezoelectric generators which require special piezoelectric materials, electrostatic converters are typically constructed of simple materials. A further advantage offered by electrostatic converters in comparison to electromagnetic generators is in relation to the relatively high output voltages produced by electrostatic converters. In contrast, electromagnetic converters produce a relatively low voltage such that the power produced thereby is not readily useable by many electronic devices.

Importantly, electrostatic converters possess an additional advantage over electromagnetic and piezoelectric generators in that electrostatic converters are uniquely adapted to survive in high-temperature environments or environments wherein heat is generated. Unfortunately, electrostatic converters suffer from a particular drawback not found in the other above-mentioned mechanical energy converters. More specifically, electrostatic converters generally require an initial activation energy with sufficiently high voltage in order to initiate the process of converting mechanical energy (i.e., vibration) into electrical energy. A separate voltage source must be provided to the electrostatic converter such that a truly self-sufficient power source may be provided which is capable of taking advantage of the vibrational energy as a viable source of renewable energy.

In view of the above-described developments in microelectronic miniaturization, there exists a need in the art for a power supply capable of providing an essentially continuous supply of power to microelectronic devices or systems in order to obviate the need for periodic replacement of expendable elements such as batteries. More specifically, there exists a need in the art for an electrostatic converter capable of generating a stable and efficient power supply by scavenging vibrational energy from the environment and wherein the electrostatic converter is itself activatable by a renewable and self-sufficient thermoelectric power source.

### BRIEF SUMMARY

The present invention specifically addresses and alleviates the above-mentioned needs associated with power supplies for microelectronic devices by providing a power supply that satisfies the requirement of a separate voltage source for electrostatic converters to initiate conversion of mechanical (i.e., vibrational) energy into electrical energy. Furthermore, the present invention provides a means for improving the overall power output of an energy-harvesting device capable of exploiting known environmental energy sources such as temperature gradients and vibrational energy.

In its broadest sense, the present invention combines a thermoelectric generator with an electrostatic converter via the appropriate electronic circuitry in order to provide a sustainable power source such as may be used in microelectronic devices. The thermoelectric generator is preferably disposed adjacent to a heat source and a heat sink and is specifically configured to convert thermal energy into electrical energy in order to generate an electrical activation energy with sufficiently high voltage. The electronic circuitry may comprise an initial energy management assembly connected to and adapted to receive and condition the electrical activation energy that is produced by the thermoelectric generator.

Following the conditioning of the electrical activation energy, the initial energy management assembly delivers the electrical activation energy to the electrostatic converter to start its operating process such that the electrostatic converter may thereafter convert vibrational energy acting thereupon into electrical energy. A final energy management assembly may be further included and may be connected to the electrostatic converter in order to condition the electrical energy produced by the electrostatic converter prior to delivery of the power to the receiving device.

### BRIEF DESCRIPTION OF THE DRAWINGS

These and other features and advantages of the various embodiments disclosed herein will be better understood with respect to the following description and drawings in which like numbers refer to like parts throughout and in which:

FIG. 1 is a schematic illustration of a power supply constructed in accordance with an embodiment of the present invention and which may be comprised of a thermoelectric generator, an initial energy management assembly, an electrostatic converter and a final energy management assembly;

FIG. 2 is a schematic diagram of the power supply in an alternative embodiment wherein the initial and final energy management assemblies are integrated into a unitary device or structure;

FIG. 3 is a schematic diagram of the power supply in a further embodiment wherein the thermoelectric generator and electrostatic converter are integrated into a unitary structure;

FIG. 4 is a schematic diagram of the power supply illustrating the integration of the thermoelectric generator and electrostatic converter arranged similar to that shown in FIG. 3 but wherein the thermoelectric generator is provided in a rounded disc or ring shape within which the electrostatic converter may be contained;

FIG. 5 is a perspective view of an in-plane thermoelectric generator illustrating the basic configuration of p-type and n-type thermoelectric legs deposited onto a substrate; and

FIG. 6 is a perspective view of a cross-plane thermoelectric generator as may be utilized in combination with the electrostatic converter.

### DETAILED DESCRIPTION

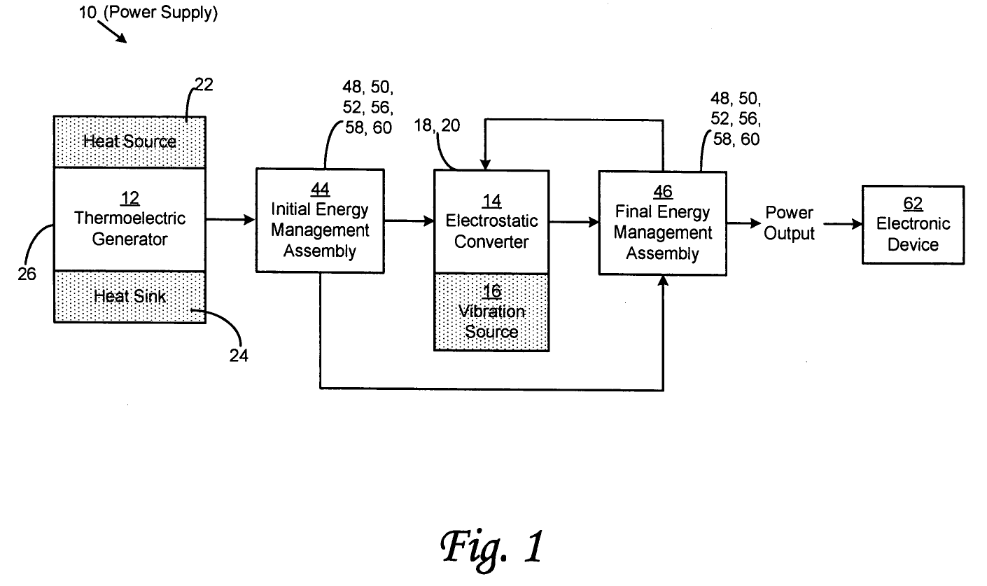

Referring now to the drawings wherein the showings are for purposes of illustrating preferred embodiments of the present invention and not for purposes of limiting the same, shown in FIG. 1 is a schematic diagram of a power supply 10 that is specifically adapted to convert mechanical energy into electrical energy. Advantageously, the power supply 10 of the present invention is adapted to produce a relatively stable and continuous supply of electrical energy sufficient to power microelectronic devices and sensor systems.

In its broadest sense, the power supply 10 comprises a thermoelectric generator 12, an initial energy management assembly 44, an electrostatic converter 14, and a final energy management assembly 46. Thermoelectric generator 12 is adapted to generate an electrical activation energy with sufficiently high voltage in response to a temperature gradient acting across the thermoelectric generator 12. The initial energy management assembly 44 is connected to the thermoelectric generator 12 and is adapted to receive the electrical activation energy therefrom and condition the electrical activation energy such that the electrical activation energy may be provided to the electrostatic converter 14 in order to initiate the mechanical-electrical energy conversion process.

The electrostatic converter 14 is connected to the initial energy management assembly 44 and is activatable by the electrical activation energy received from the initial energy management assembly 44. The electrostatic converter 14 is then capable of generating electrical energy in response to vibrational energy acting thereupon. The final energy management assembly 46 is connected to the electrostatic converter 14 and is adapted to condition the electrical energy produced thereby for use by any number of electronic devices 62 such as microelectronic devices and sensor systems.

Advantageously, the power supply 10 of the present invention is uniquely suitable for environments that facilitate scavenging thermal energy from relatively small temperature gradients. In addition, the power supply 10 is adapted for use in environments facilitating scavenging of mechanical energy in the form of vibrations for conversion into electrical energy. Such thermal energy may be available in a variety of forms such as dissipated heat produced by the human body or waste heat produced by a microwave or gas motor or electric motor which, advantageously, also typically vibrate during operation. The power supply 10 is therefore uniquely suited to harvest both thermal and mechanical energy from a single environmental source such as an electric motor in order to provide a self-sufficient and stable power source for various electronic devices 62 in situations where it is impractical or impossible to power such devices utilizing wired power sources or batteries.

Referring now to FIG. 1, shown is the power supply 10 wherein the thermoelectric generator 12 may be configured as an in-plane thermoelectric generator 12 configuration similar to that shown and described in U.S. Pat. No. 6,958,443 and entitled LOW POWER THERMOELECTRIC GENERATOR, issued to Stark et al., the entire contents of which is expressly incorporated by reference herein. Another version of the in-plane thermoelectric generator 12 for use in the present invention may be similar to that which is disclosed in U.S. patent application Ser. No. 11/352,113 filed on Feb. 10, 2006 by Stark and entitled LOW POWER THERMOELECTRIC GENERATOR, the entire contents of which is also expressly incorporated by reference herein.

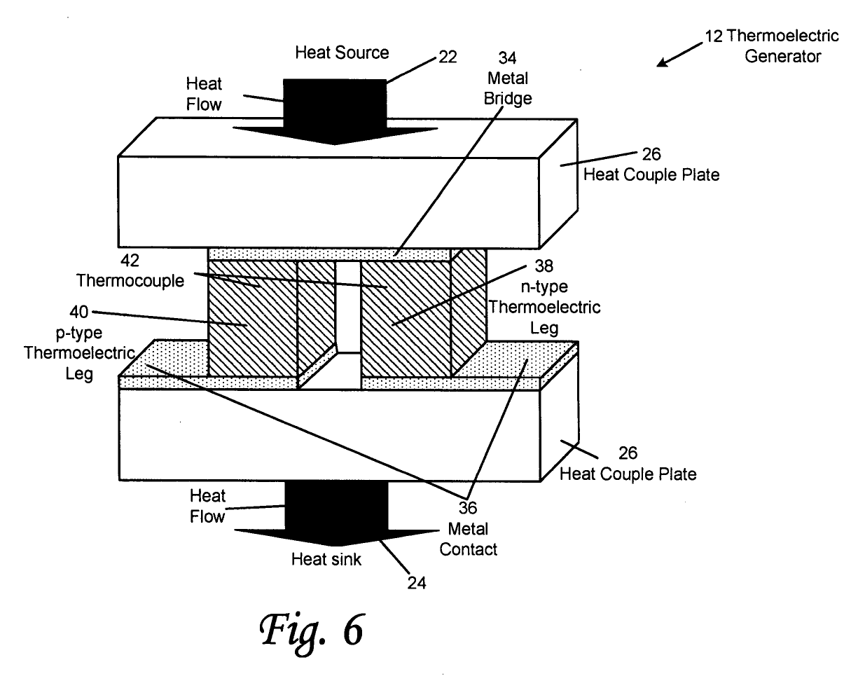

Furthermore, the thermoelectric generator 12 may be configured in a cross-plane configuration wherein n-type and p-type thermoelectric legs 38, 40 are formed in a checkerboard arrangement on a substrate as is shown in FIG. 6 and which is described in greater detail below. Preferably, such cross-plane thermoelectric generator 12 is configured to provide energy at a relatively high voltage level. In general, the thermoelectric generator 12 is configured as any suitable thermal energy-conversion device capable of generating an electrical activation energy with sufficiently high voltage for starting the electrostatic energy conversion process in the electrostatic generator 14.

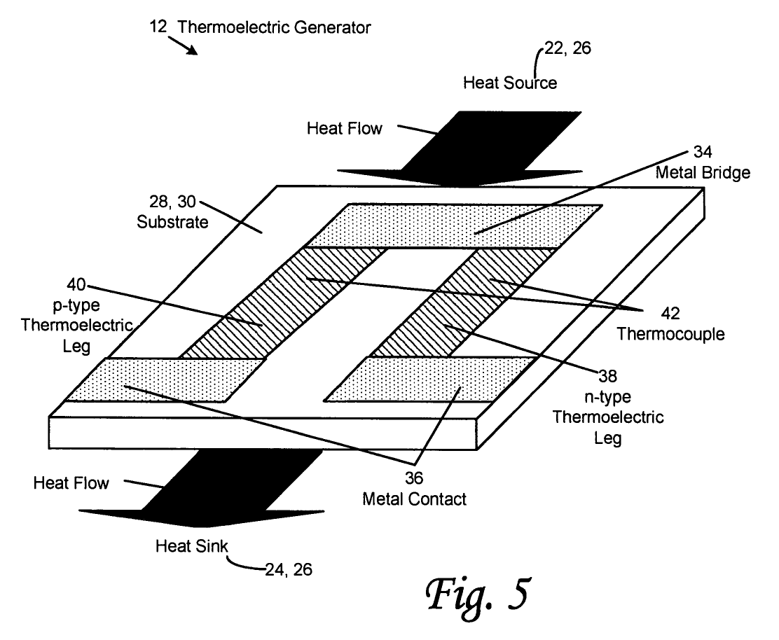

As best seen in FIG. 5, the in-plane thermoelectric generator 12 configuration may generally be comprised of at least one substrate 30 and a spaced pair of heat couple plates 26 for thermal connection to a heat source 22 and a heat sink 24. The substrate 30 is preferably oriented orthogonally relative to the heat couple plates 26 and is in thermal communication therewith. The substrate 30 may have opposing front and back substrate surfaces upon which may be deposited a plurality of thermocouples 42 which comprise elongate alternating n-type and p-type thermoelectric legs 38, 40 disposed in spaced parallel arrangement to one another.

Each of the n-type and p-type thermoelectric legs 38, 40 may be formed of a thermoelectric material. Each one of the p-type thermoelectric legs 40 is electrically connected to an adjacent one of the n-type thermoelectric legs 38 at opposite ends of the p-type thermoelectric legs 40 such that the series of n-type and p-type thermoelectric legs 38, 40 are electrically connected in series and thermally connected in parallel. Thermal gradient from the top heat couple plate to the bottom heat couple plate results in heat flow across the n-type and p-type thermoelectric legs 38, 40 which results in the production of electrical energy. The top heat couple plate 26 is thermally connected to the heat source 22 and the bottom heat couple plate 26 is thermally connected to the heat sink 24.

One arrangement of the in-plane thermoelectric generator 12 may include a plurality of foil segments 28 electrically connected in series and thermally connected in parallel and which may be interposed between the top heat couple plate 26 and the bottom heat couple plate 26. The foil segments 28 may be oriented in parallel, spaced arrangements such as that disclosed in U.S. Pat. No. 6,958,443, as mentioned above. Alternatively, the foil segments 28 may be spirally-wound similar to that which is shown and disclosed in U.S. patent application Ser. No. 11/352,113.

Regardless of the arrangement, the foil segments 28 are electrically connected in series with each foil segment 28 comprising a substrate 30 having a plurality of thermocouples 42 disposed thereon and which comprise alternating n-type and p-type thermoelectric legs 38, 40 disposed in spaced parallel arrangement. The p-type and n-type thermoelectric legs 40, 38 which make up the thermocouples 42 are connected using metal bridges 34 with metal contacts 36 joining the n-type and p-type thermoelectric legs 38, 40 of adjacent foil segments 28 as is shown in FIG. 5. Such metal bridges 34 and metal contacts 36 may be deposited onto the substrate 30 in combination with deposition of the p-type and n-type thermoelectric legs 40, 38 in order to form the thin film thermoelectric structure that makes up the in-plane thermoelectric generator 12 configuration.

Each of the n-type and p-type thermoelectric legs 38, 40 is preferably formed of a suitable thermoelectric material. In-plane thermoelectric generators 12 are typically adapted to convert thermal energy into electrical energy using small temperature differences across the ends of the thermoelectric legs 38, 40. The characteristic of such electrical energy is typically a low power output but at a relatively high voltage. In-plane thermoelectric generators 12 are manufacturable by a variety of techniques including thin film technology. In spite of their relatively low power output, in-plane thermoelectric generators 12 are useful for supplying energy for certain electronic devices 62, as well as supplying power to an initial energy management assembly 44 as well as activating certain other devices such as the electrostatic converter 14 of the present invention.

It should also be noted that the in-plane thermoelectric generator 12 may be fabricated using MEMS silicon-based technology such as that which is described on pages 246-250 of the document entitled “A Thermoelectric Converter for Energy Supply” by H. Glosch et al. and reprinted in the publication entitled Sensors and Actuators, No. 74 (1999), the contents of which is herein incorporated by reference in its entirety. Additionally, the in-plane thermoelectric generator 12 may be fabricated using silicon technology such as that which is described in the document entitled “Miniaturized Thermoelectric Generators Based on Poly-Si and Poly-SiGe Surface Micromachining” by M. Strasser et al. of Infineon Technologies A.G., Wireless Products, Microsystems and Munich University of Technology, Institute for Physics of Electrotechnology, the contents of which is herein incorporated by reference in its entirety.

A further description of silicon-based technology for fabricating the in-plane thermoelectric generator 12 is provided in the document entitled “Analysis of a CMOS Low Power Thermoelectric Generator” by M. Strasser et al. of Infineon Technologies and Munich University of Technology, the contents of which is herein incorporated by reference in its entirety. The in-plane thermoelectric generator 12 may further be fabricated using electroplating technology similar to that disclosed on pages 146-152 of the document entitled “Microfabrication of Thermoelectric Generators on Flexible Foil Substrates as Power Source for Autonomous Microsystems” by Wenmin Qu et al. and published in The Journal of Micromechanics and Microengineering, 11 (2001), the contents of which is herein incorporated by reference in its entirety. In this method, the in-plane thermoelectric generator 12 is constructed as an arrangement of Sb—Bi thermocouple strips embedded within an epoxy film and utilizes a series of foil lithography, electroplating, embedding and wet chemical etching steps in order to form the in-plane thermoelectric generator 12.

Referring to FIG. 6, the cross-plane thermoelectric generator 12 as shown in FIG. 6 may be fabricated using polycrystalline bulk material such as is utilized in standard Peltier coolers as is known in the art. In this configuration, the length of the p-type and n-type thermoelectric legs 40, 38 is typically in the millimeter range for configurations utilizing polycrystalline bulk material. The heat couple plates 26 are arranged on upper and lower ends of the spaced pair of thermoelectric legs 38, 40 in order to thermally connect to a heat source and heat sink 22, 24, respectively, for facilitating heat flow through the thermoelectric legs 38, 40.

The cross-plane thermoelectric generator 12 may be fabricated by a variety of alternative technologies known in the art. For example, the cross-plane thermoelectric generator 12 may be fabricated in a manner described in the document entitled “Micropelt Miniaturized Thermoelectric Devices: Small Size, High Cooling Power Densities, Short Response Time” by H. Boettner of the Fraunhofer Institute Physikalische Messtechnik (IPM), Freiburg, Germany, or in the article entitled “Micropelt: State of the Art, Roadmap and Applications” also by H. Boettner as well as that which is described in the document entitled “New Thermoelectric Components Using Microsystem Technologies” also by H. Boettner et al. , the contents of each being herein incorporated by reference in their entirety.

In the above-noted articles, the cross-plane thermoelectric generator 12 may be fabricated by depositing (e.g. sputtering) several layers of relatively thick (e.g., 10 microns) polycrystalline Bi₂Te₃ n-type material and (Bi, Sb)₂Te₃ p-type material onto wafers having pre-structured electrodes. Following an annealing process, the n-type and p-type layers are joined by depositing a high-temperature solder. Etching is used to define the n-type and p-type thermoelectric legs 38, 40 after which the heat couple plates are soldered together.

In addition, the cross-plane thermoelectric generator 12 may be fabricated using electroplating technology (e.g., galvanic processing technology) such as that which is described in the disclosure entitled “Thermoelectric Microdevice Fabricated by a MEMS-Like Electrochemical Process” by G. Jeffrey Snyder et al. of Jet Propulsion Laboratory, California Institute of Technology and published on-line on 27 Jul. 2003, the contents of which is herein incorporated by reference in its entirety.

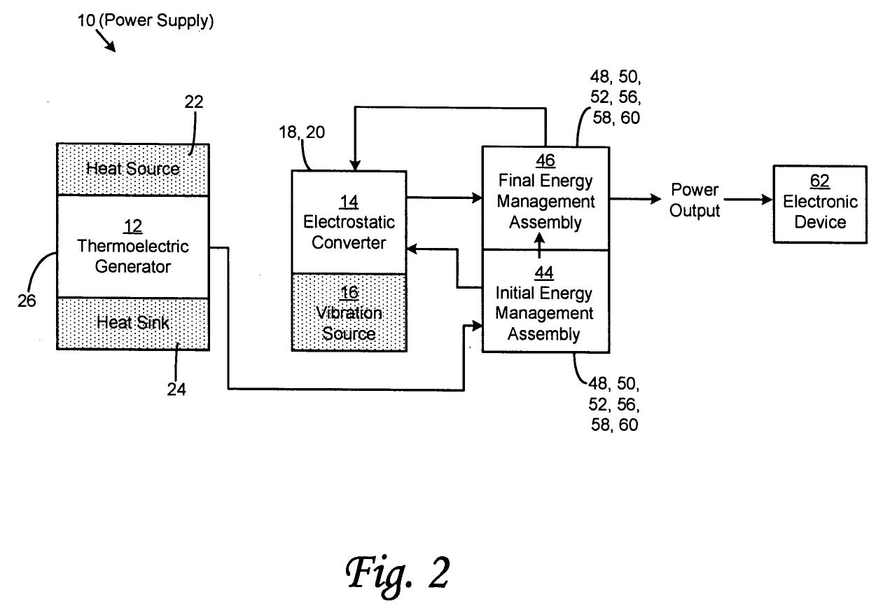

Referring to FIG. 2, the thermoelectric generator 12 is connected to the initial energy management assembly 44 which is specifically configured to condition the electrical activation energy produced by the thermoelectric generator 12. The initial energy management assembly 44 receives the electrical activation energy from the thermoelectric generator 12. Furthermore, the initial energy management assembly 44 may be adapted to rectify and limit the thermoelectric voltage produced by the thermoelectric generator 12, protect against the generation of excess voltage, initially provide energy storage capability in the form of an energy storage element 56, as well as provide the capability of voltage regulation to regulate the point at which power is released to the electrostatic converter 14.

Rectifying of the thermoelectric voltage may be facilitated through the use of a diode 50 in order to provide voltage with only one polarity regardless of the direction of temperature flow or temperature gradient. Alternatively, a rectifier 48 may be adapted to enable exploitation of temperature gradient regardless of the direction of heat flow by utilizing a diode bridge 52. Further embodiments may include at least one diode to block the discharge of stored energy by the initial energy management assembly 44.

The initial energy management assembly 44 may also provide excess voltage protection such as by utilizing a Zener diode, a single diode 50 or a plurality of diodes 50 arranged in series in a manner well known in the art. In a broad sense, the initial energy management assembly 44 preferably provides excess voltage protection in order to limit the generation of harmful thermoelectric voltages such as may occur at relatively high temperature gradients across the thermoelectric generator 12. Energy storage elements 56 may include small capacitors 58 or a rechargeable thin film battery 60 configured to accumulate sufficient energy in order to activate the electrostatic converter 14. Voltage detection may be facilitated through the use of a switch or switches at defined voltage thresholds which correspond to the amount of energy stored. Over a pre-determined threshold, charges in the storage element may be released as power to the electrostatic converter 14. Below the predetermined threshold, electrical current flow may be interrupted or prevented.

The electrostatic converter 14 is configured to convert mechanical energy from vibration under the principle of work performed against an electric field formed between two plates of a variable capacitor 58. The electrostatic converter 14 may be constructed similar to that disclosed in a publication entitled “Vibration-to-Electric Energy Conversion” by S. Meninger et al. and published by IEEE under Transactions on Very Large Scale Integration (VLSI) Systems, Vol. 9, No. 1 February 2001, (hereinafter “the Meninger reference”) the entire contents of which is herein incorporated by reference in its entirety.

In addition, the electrostatic converter 14 may be constructed similar to that disclosed in the publication entitled “Micro-Machined Variable Capacitors for Power Generation” by P. Miao et al. of the Optical and Semi-Conductor Devices Group of the Department of Electrical and Electronic Engineering of the Imperial College, London, UK, the entire contents of which is herein incorporated by reference in its entirety. Also, construction or arrangement of the electrostatic converter 14 may be similar to that which is disclosed in the document entitled “MEMS Electrostatic Micropower Generator for Low Frequency Operation” by P. D. Mitcheson et al. of the Imperial College, London, UK, and which document is available on-line as of Jun. 1, 2004, the entire contents of which is herein incorporated by reference in its entirety. In addition, the electrostatic converter 14 may be constructed similar to that disclosed in the publication entitled “Micro-electrostatic Vibration-to-Electricity Converters” by Shad Roundy et al. of the University of Berkeley, California and published under document number IMECE2002-39309, the entire contents of which is herein incorporated by reference in its entirety.

The electrostatic converter 14 may be fabricated by means of micro-machining of the variable capacitor 58. The variable capacitor 58 produces electrical energy as a result of mechanical forces (i.e., vibrations) acting against an electric field formed between a pair of plates 18 separated by a dielectric 20. In this regard, the variable capacitor 58 converts vibrational energy into electrical energy by altering the distance between the pair of plates 18 in response to relative vibrational movement occurring between the plates 18. The geometric size and spacing of the plates of the variable capacitor determines the capacitance. Movement of a base plate in relation to a top plate allows for the extraction of charge such as by means of a power extraction circuit.

The electrostatic converter 14 may be operated under two different modes: charge-constrained and voltage-constrained. A description of the charge-constrained and voltage-constrained modes of operation is provided in the Meninger reference and in the publication entitled “Micro-electrostatic Vibration-to-Electricity Converters” by Roundy mentioned above. In the charge-constrained mode, charge in the variable capacitor 58 is constrained such that voltage increases as capacitance decreases due to an increase in spacing between the plates from an initial gap to a final gap. In the charge-constrained mode, the electrostatic converter 14 requires a single separate voltage source such as may be generated by the thermoelectric generator 12 in order to activate the electrostatic converter 14.

Capacitance of the variable capacitor oscillates between a maximum and a minimum capacitance in response to vibrations induced by a vibration source such as by an electric motor as mentioned above. The thermoelectric generator 12 generates an electrical activation energy with sufficiently high voltage generated in response to a temperature gradient. The activation energy is delivered to the electrostatic converter when the variable capacitor is at its maximum capacity (Cₘₐₓ). The activation energy or charge is transferred by closing a circuit such as by activating a first switch so that energy may flow from the thermoelectric generator 12 (i.e., via the initial energy management assembly 44) to the variable capacitor.

The first switch is then opened in timing with the vibrational frequency such that the variable capacitor moves from Cₘₐₓ to a position of minimum capacitance (Cₘᵢₙ) when there is an open circuit between the initial energy management assembly 44 and the variable capacitor. The decrease in capacitance from Cₘₐₓ to Cₘᵢₙ results in an increase in voltage across the variable capacitor. At Cₘᵢₙ, charge stored in the variable capacitor is then delivered at an increased voltage to a storage device such as a separate capacitor of the final energy management assembly 46 by closing a circuit therebetween such as by activating a second switch. The cycle repeats in this manner resulting in the creation of electrical energy as a result of oscillations between Cₘₐₓ and Cₘᵢₙ due to vibration.

Operation and arrangement of the electrostatic converter 14 in the voltage-constrained mode is initiated by first charging the variable capacitor to a maximum voltage Vₘₐₓ from a storage element fed by a separate voltage source such as a thermoelectric generator 12. The value of Vₘₐₓ may be determined by the maximum voltage capability of switches in the circuitry or by a maximum field limit of the variable capacitor itself. The voltage across the plates of the variable capacitor is held constant by means of an additional voltage source as the plates move under vibrational force from Cₘₐₓ to Cₘᵢₙ during which a portion of the charge moves from the variable capacitor to a storage element such as a capacitor which may be included in the final energy management assembly 46. The additional voltage source may be provided by an additional thermoelectric generator 12.

Notably, although the charge-constrained version of the electrostatic converter produces less energy than that available in the voltage-constrained case, a separate voltage source is required for voltage-constrained version in order to maintain a constant voltage across the plates of the variable capacitor as it moves from Cₘₐₓ to Cₘᵢₙ. Therefore, the power supply of the present invention is preferably arranged to operate in the charge-constrained mode wherein the thermoelectric generator 12 may advantageously provide a self-sufficient and renewable activation energy to the variable capacitor of the electrostatic converter. Importantly, the unique combination of the thermoelectric generator 12 with the electrostatic converter provides the power supply of the present invention as a completely renewable and self-sufficient power source.

Referring still to FIG. 1, the final energy management assembly 46 is connected to the electrostatic converter 14 as shown and is specifically adapted to condition the electrical energy produced by the electrostatic converter 14 in a manner similar to that described above for the initial energy management assembly 44. More specifically, the final energy management assembly 46 is adapted to condition the electrical energy for use by an electrical device connected to the final energy management assembly 46.

The final energy management assembly 46 may include a controller to operate the electrostatic converter 14 and to transform voltage produced by the electrostatic converter 14 to a usable level for driving and powering the electronic device 62. Optionally, the controller may reduce electromagnetic noise and stabilize the voltage for use by the electronic device 62. In addition, the final energy management assembly 46 may advantageously include an energy storage element 56 such as a small capacitor 58 or a rechargeable thin film battery 60 in order to accumulate sufficient electrical energy to power the electronic device 62 connected to the power supply 10 of the present invention.

In addition, the energy storage element 56 may be utilized to provide the electrical activation energy for the electrostatic converter 14 enabling a reduction in the size and complexity of the initial energy management assembly 44 as well as in the thermoelectric generator 12. Voltage detection may be further provided by the final energy management assembly 46 to regulate the threshold at which power is released. Voltage detection may be facilitated using functional switches operating at pre-determined voltage thresholds. When the voltage reaches a pre-determined threshold, the electrical charge in the storage element is released to the electronic device 62. In addition, a portion of the electrical energy may be released back to the electrostatic converter 14 in order to continue its conversion cycle. Below the pre-determined voltage threshold, electrical current supply to the electronic device 62 is interrupted or prevented.

The power supply 10 may be provided in alternative embodiments illustrated in FIGS. 2-4. For example, as shown in FIG. 2, the initial and final energy management assemblies may be combined into a unitary device such that the power supply 10 comprises three general components: the thermoelectric generator 12, the electrostatic converter 14, and the energy management assemblies 44, 46. All components may be interconnected in a manner similar to that shown in FIG. 1.

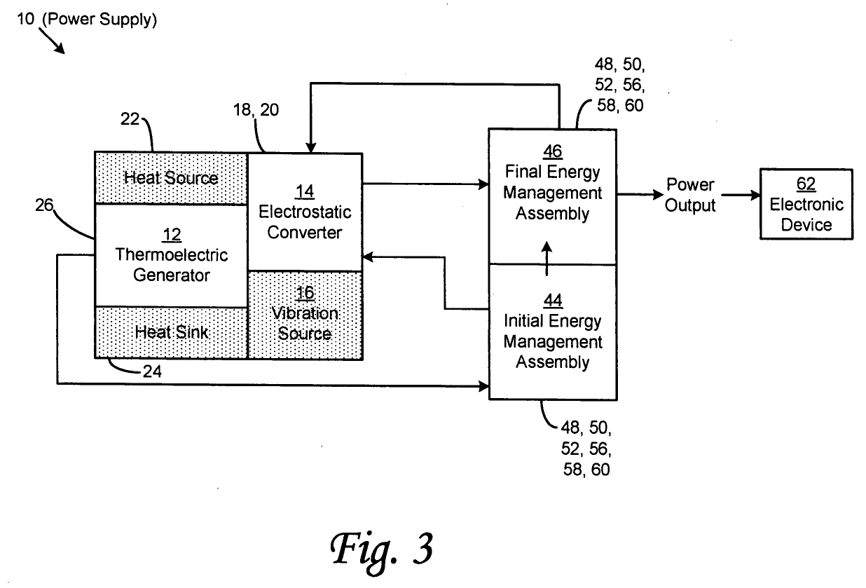

In FIG. 3, the power supply 10 may be arranged in yet another embodiment wherein the thermoelectric generator 12 and electrostatic converter 14 are integrated into a unitary device. For example, it may be advantageous to manufacture the electrostatic converter 14 and the thermoelectric generator 12 utilizing silicon-based technology and micro-electro-mechanical systems (MEMS) technology in order to facilitate integration and miniaturization with a silicon-based microelectronic device which the electrostatic converter 14 may be powering. For example, the thermoelectric generator 12 and electrostatic converter 14 may be fabricated as an on-chip device in combination with the microelectronic component to be powered by the power supply 10.

In yet another arrangement, the thermoelectric generator 12 and electrostatic converter 14 may be constructed as a hybrid device wherein the electrostatic converter 14 is fabricated using silicon-based technology while the thermoelectric generator 12 is manufacturing using non-silicon-based microtechnology similar to that shown and disclosed in U.S. Pat. No. 6,958,443. More specifically, U.S. Pat. No. 6,958,443 discloses a Bi₂Te₃-based thermoelectric material system. In the arrangement shown in FIG. 3, the initial and final energy management assemblies may be constructed as a unitary structure similar to that shown in FIG. 2 and described above.

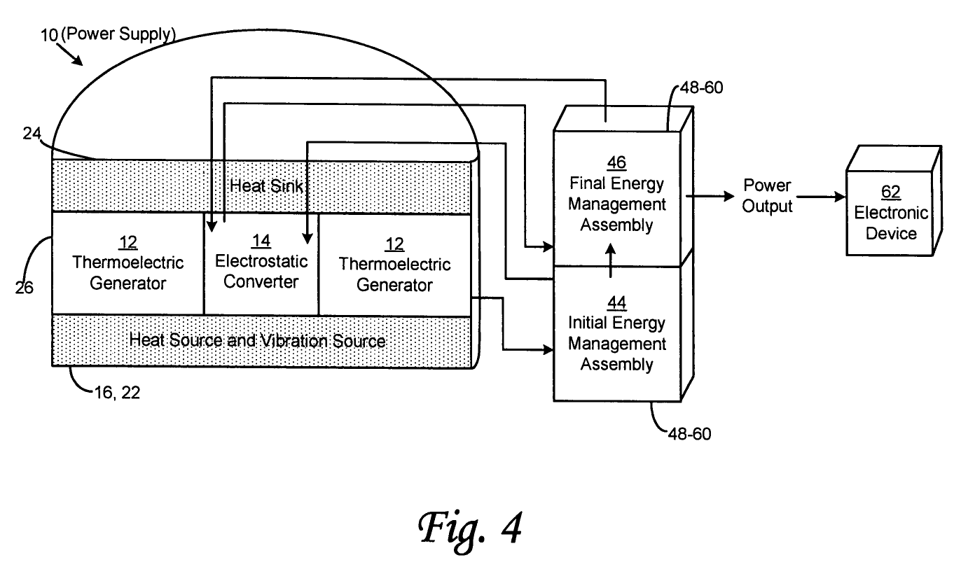

In yet another embodiment, the power supply 10 may be arranged similar to that shown in FIG. 4 wherein the thermoelectric generator 12 is arranged as a ring or spiral of foil segments 28 similar to that shown and disclosed in U.S. patent application Ser. No. 11/352,113 and which is entitled LOW POWER THERMOELECTRIC GENERATOR. As disclosed, the spiral-wound arrangement of the thermoelectric generator 12 provides an opportunity for integrating the electrostatic converter 14 in an aperture or opening formed in a center portion of the thermoelectric generator 12.

In the spiral arrangement, the in-plane thermoelectric generator 12 may be arranged as a spiral of a continuous substrate 30 or of interconnected substrate 30 segments wherein a relatively large number of thermoelectric legs 38, 40 are connected in series and wherein substrate 30 segments may be connected end-to-end using metal contacts 36 between the substrates 30 to electrically connect the n-type and p-type thermoelectric legs 38, 40 in series. The spiral or stack of the thermopile structure may have the heat couple plates 26 disposed on upper and lower ends in order to connect to the heat source 22 and heat sink 24. It is also contemplated that each of the components that make-up the power supply 10 may be integrated into a unitary structure and encapsulated to form a convenient assembly which may be adapted for use in many common microelectronic devices.

Electrical connection between components in FIG. 4 is identical of that described above and shown in FIGS. 1-3. Additionally, it is contemplated that the components that make up the power supply 10 of the present invention may be integrated into a single encapsulated device such as based on MEMS technology and a silicon-based technology. Such device may be fabricated on-chip or as a hybrid device constructed similar to that described above as an electrostatic converter 14 using silicon-based technology and the thermoelectric generator 12 utilizing non-silicon microtechnology.

Operation of the power supply 10 will now be described with reference to FIGS. 1-6. The thermoelectric generator 12 is preferably disposed between a suitable heat source 22 and heat sink 24 in order to convert thermal energy directly into electrical energy to supply the initial electrical activation energy to the initial energy management assembly 44. Due to discontinuities or variations in temperature differential, such electrical activation energy is likely manifested as a relatively irregular or discontinuous energy flow requiring continuous conditioning into a stable and consistent electrical energy output.

Accordingly, the initial energy management assembly 44 rectifies and limits the electrical activation energy and creates an electrical charge within an optional energy storage element 56 such as a capacitor 58 or a small rechargeable thin film battery 60. Additionally, the initial energy management assembly 44 is configured to detect the state of the charge of the energy storage element 56 utilizing a voltage detector. Upon attainment of the predetermined voltage level, the electrical activation energy can be released in the appropriate voltage level to the electrostatic converter 14.

The electrostatic converter 14 then generates electrical energy upon receipt of the electrical activation energy from the initial energy management assembly 44. As was described above, the electrostatic converter 14 is specifically adapted to generate electrical energy as a result of mechanical energy (i.e., vibrations) acting at the vibration source 16. The electrostatic converter 14 thereby supplies electrical energy to a final energy management assembly 46 which, like the initial energy management assembly 44, conditions the power provided thereby in order to drive the final electronic device 62. In addition, a portion of the energy may be tapped from the supply to the electronic device 62 for driving the electrostatic converter 14.

Optionally, the final energy management assembly 46 may further include a relatively large energy storage element 56 such as a rechargeable thin film battery 60 which may be charged with excess energy - energy that is not used by the final electronic device 62 or the electrostatic converter 14. Further, excess electrical energy produced by the thermoelectric generator 12 but which is not provided to the electrostatic converter 14 may also be stored in a relatively large energy storage element 56 of the final energy management assembly 46 in order to extend the operational time of the final electronic device 62.

The description of the various embodiments of the present invention is presented to illustrated preferred embodiments thereof and other inventive concepts may be otherwise variously embodied and employed. The appended claims are intended to be construed to include such variations except insofar as limited by the prior art.

What is claimed is:

1. A power supply, comprising:
a thermoelectric generator adapted to generate an electrical activation energy with sufficiently high voltage generated in response to a temperature gradient acting across the thermoelectric generator; and
an electrostatic converter connected to the thermoelectric generator and being activatable by the electrical activation energy received therefrom and being configured to generate electrical energy in response to vibrational energy acting thereupon.

2. The power supply of claim 1 wherein the electrostatic converter is configured to convert vibrational energy into electrical energy in a charge-constrained mode.

3. A power supply, comprising:
a thermoelectric generator adapted to generate an electrical activation energy with sufficiently high voltage generated in response to a temperature gradient acting across the thermoelectric generator;
an initial energy management assembly connected to and adapted to receive and condition the electrical activation energy produced by the thermoelectric generator;
an electrostatic converter connected to the initial energy management assembly and being activatable by the electrical activation energy received therefrom and being configured to generate electrical energy in response to vibrational energy acting thereupon; and
a final energy management assembly connected to the electrostatic converter and being adapted to condition the electrical energy produced thereby.

4. The power supply of claim 3 wherein the thermoelectric generator and electrostatic converter are integrated into a unitary electronic assembly.

5. The power supply of claim 3 wherein the initial and final energy management assemblies are integrated into a unitary electronic assembly.

6. The power supply of claim 3 wherein the thermoelectric generator, electrostatic converter, and initial and final energy management assemblies are integrated into a unitary electronic assembly.

7. The power supply of claim 3 wherein the electrostatic converter is configured to convert vibrational energy into electrical energy in a voltage-constrained mode.

8. The power supply of claim 3 wherein the electrostatic converter is configured to convert vibrational energy into electrical energy in a charge-constrained mode.

9. The power supply of claim 8 wherein:
the electrostatic converter includes a variable capacitor having a spaced pair of conductor plates movable between an initial gap and a relatively larger final gap;
the initial energy management system being configured to provide the electrical activation energy to the variable capacitor at an initial voltage when the conductor plates are spaced at the initial gap at which the variable capacitor has a maximum capacitance;
the electrostatic converter being configured to increase the spacing between the conductor plates from the initial gap to the final gap in response to the vibrational energy acting thereupon causing a decrease in capacitance and an increase in voltage from the initial voltage to a maximum voltage;
the electrostatic converter being further configured to extract charge from the variable capacitor at the maximum voltage for delivery to a storage element.

10. The power supply of claim 3 wherein at least one of the thermoelectric generator and electrostatic converter is fabricated using silicon-based technology.

11. The power supply of claim 10 wherein at least one of the thermoelectric generator and electrostatic converter is fabricated using a complementary metal-oxide semiconductor (CMOS) fabrication process.

12. The power supply of claim 3 wherein at least one of the thermoelectric generator and electrostatic converter is fabricated using micro-electro-mechanical system (MEMS) technology.

13. The power supply of claim 3 wherein the thermoelectric generator includes a plurality of n-type and p-type thermoelectric legs formed of a bulk polycrystalline thermoelectric material.

14. The power supply of claim 3 wherein the thermoelectric generator is fabricated using electroplating technology.

15. The power supply of claim 3 wherein the thermoelectric generator has an in-plane configuration.

16. The power supply of claim 15 wherein the in-plane thermoelectric generator is fabricated using thin-film technology.

17. The power supply of claim 16 wherein the in-plane thermoelectric generator comprises:
a spaced pair of heat couple plates;
at least one substrate in thermal communication with the heat couple plates, the substrate having opposing front and back substrate surfaces, the substrate being formed of an electrically insulating material having a low thermal conductivity; and
a series of elongate alternating n-type and p-type thermoelectric legs disposed in spaced parallel arrangement on at least one of the front and back substrate surfaces, each of the n-type and p-type legs being formed of a thermoelectric material;
wherein each one of the p-type thermoelectric legs is electrically connected to an adjacent one of the n-type thermoelectric legs at opposite ends of the p-type thermoelectric legs such that the series of n-type and p-type thermoelectric legs are electrically connected in series and thermally connected in parallel.

18. The power supply of claim 17 wherein the n-type and p-type thermoelectric legs are formed of a Bi₂Te₃-type thermoelectric material.

19. The power supply of claim 17 wherein the in-plane thermoelectric generator comprises:
a plurality of spaced parallel foil segments electrically connected in series and thermally connected to and interposed between the heat couple plates, each one of the foil segments comprising:
a substrate having opposing front and back substrate surfaces;
wherein the alternating n-type and p-type thermoelectric legs are disposed in spaced parallel arrangement on at least one of the front and back substrate surfaces.

20. The power supply of claim 17 wherein the in-plane thermoelectric generator comprises:
a spirally wound foil segment captured between and thermally interconnecting the heat couple plates, the foil segment comprising:
an elongate substrate having opposing front and back substrate surfaces;
wherein the alternating n-type and p-type thermoelectric legs are disposed in spaced parallel arrangement on at least one of the front and back substrate surfaces.

21. The power supply of claim 3 wherein the thermoelectric generator has a cross-plane configuration.

22. The power supply of claim 21 wherein the cross-plane thermoelectric generator comprises:
a spaced pair of heat couple plates;
a series of elongate alternating n-type and p-type thermoelectric legs oriented orthogonally relative to the heat couple plates and being in thermal communication therewith, each of the n-type and p-type legs being formed of a thermoelectric material;
wherein each one of the p-type thermoelectric legs is electrically connected to an adjacent one of the n-type thermoelectric legs at opposite ends of the p-type thermoelectric legs such that the series of n-type and p-type thermoelectric legs are electrically connected in series and thermally connected in parallel.

23. The power supply of claim 22 wherein the n-type and p-type thermoelectric legs are formed of a Bi₂Te₃-type thermoelectric material.

24. A thermoelectric generator configured to provide an electrical activation energy with sufficiently high voltage to a power supply having an electrostatic converter configured to generate electricity in response to vibrational energy acting upon the electrostatic converter.

25. The thermoelectric generator of claim 24 configured in an in-plane configuration comprising:
a spaced pair of heat couple plates;
a substrate oriented orthogonally relative to the heat couple plates and being in thermal communication therewith, the substrate having opposing front and back substrate surfaces; and
a series of elongate alternating n-type and p-type thermoelectric legs disposed in spaced parallel arrangement on at least the front substrate surface, each of the n-type and p-type legs being formed of a thermoelectric material;
wherein each one of the p-type thermoelectric legs is electrically connected to an adjacent one of the n-type thermoelectric legs at opposite ends of the p-type thermoelectric legs such that the series of n-type and p-type thermoelectric legs are electrically connected in series and thermally connected in parallel.

26. The thermoelectric generator of claim 24 configured in a cross-plane configuration comprising:
a spaced pair of heat couple plates;
a series of elongate alternating n-type and p-type thermoelectric legs oriented orthogonally relative to the heat couple plates and being in thermal communication therewith, each of the n-type and p-type legs being formed of a thermoelectric material;
wherein each one of the p-type thermoelectric legs is electrically connected to an adjacent one of the n-type thermoelectric legs at opposite ends of the p-type thermoelectric legs such that the series of n-type and p-type thermoelectric legs are electrically connected in series and thermally connected in parallel.
